(19) United States
(12) Patent Application Publication
(10) Pub. No.: US 2007/0009813 A1
(43) Pub. Date: Jan. 11, 2007

(54) METHOD OF MANUFACTURING LIQUID CRYSTAL DISPLAY DEVICE

(75) Inventor: Yasuo FUJITA, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Chiyoda-ku (JP)

(21) Appl. No.: 11/425,259

(22) Filed: Jun. 20, 2006

(30) Foreign Application Priority Data
Jul. 5, 2005 (JP) 2005-195722

(51) Int. Cl. G03F 9/00

(52) U.S. Cl. 430/22

(57) ABSTRACT

A plurality of display areas are formed on an array substrate by stepper exposure. The array substrate is divided into array shot areas serving as shot units at the time of divided exposure. One display area is divided into four array shot areas. One array shot area is provided with at least one alignment mark. The array substrate has a rectangular shape, and is provided with a superimposition mark at the corner thereof which is used as the reference for superimposing the array substrate and a CF substrate.

### BACKGROUND OF THE INVENTION

1. Field of the Invention

The present invention relates to methods of manufacturing liquid crystal display devices, and more particularly to techniques of improving alignment accuracy between an array substrate and a color filter substrate.

2. Description of the Background Art

With recent improvements in accuracy and display quality of liquid crystal display devices, there has been a growing demand for alignment accuracy between an array substrate and a color filter substrate.

In order to improve the alignment accuracy, it is important not just to superimpose the array substrate and color filter substrate without deviation, but to accurately form the respective pattern positions of the substrates without deviation.

Assuming that an area corresponding to one display substrate mounted on one liquid crystal display device is called a display area, both the array substrate and the color filter substrate have a plurality of display areas formed together on one big glass substrate, are superimposed on one another, and then divided in units of the display area.

Various methods of accurately making both substrates have been proposed. For example, Japanese Patent Application Laid-Open No. 2002-287106 discloses a method of preventing the occurrence of positional accuracy deviation after superimposing the substrates, by providing each display area with an alignment mark for exposure, measuring in advance positional distribution of the alignment marks on the array substrate side, and making the color filter substrate in accordance with measured deviation.

In addition, Japanese Patent Application Laid-Open No. 9-127546 (1997) discloses a method of superimposing the substrates with pixels at the corners of the display areas as alignment marks.

Further, Japanese Patent Application Laid-Open No. 2000-133579 discloses a method of measuring the amount of positional deviation in a sample shot on a substrate to be exposed or an in-shot error component, and correcting each shot based on the measurement.

A large liquid crystal display device sometimes includes a display area that is bigger than a shot area. When manufacturing such device, positional deviations cannot always be corrected appropriately by the techniques disclosed in the above Japanese patent applications.

### SUMMARY OF THE INVENTION

An object of the present invention is to provide a method of manufacturing a liquid crystal display device capable of appropriately correcting a positional deviation.

In a first aspect of the invention, a method of manufacturing a liquid crystal display device having a first substrate and a second substrate being oppositely arranged includes the steps of: making a first substrate; making a second substrate; determining a positional deviation; and correcting a position. In the step of making a first substrate, a first substrate is made while forming at least one first alignment mark in each of a plurality of first shot areas, the first shot areas being divided by divided exposure and smaller than a display area on the first substrate. In the step of making a second substrate, a second substrate is made while forming a second alignment mark corresponding to the first alignment mark in each of first shot corresponding areas, the first shot corresponding areas corresponding on the second substrate to the first shot areas. In the step of determining a positional deviation, a positional deviation of the first alignment mark from the second alignment mark is determined. In the step of correcting a position, a position of each of the first shot areas is corrected in accordance with a position of each of the first shot corresponding areas based on the positional deviation determined by the positional deviation determining step.

The positional deviation can therefore be corrected appropriately even when the display area is larger than the array shot area, thus improving the alignment accuracy between the first substrate and the second substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view illustrating an example of an array substrate according to a first preferred embodiment of the present invention;

FIG. 2 is a top view illustrating another example of the array substrate according to the first preferred embodiment;

FIGS. 3 and 4 are top views illustrating the configuration of an alignment mark according to the first preferred embodiment;

FIG. 5 is a cross-sectional view illustrating the structure of a liquid crystal display device according to the first preferred embodiment;

FIGS. 6A to 6D are schematic views showing positional corrections of array shot areas according to the first preferred embodiment;

FIG. 7 is a top view illustrating an array substrate on which an offset is performed according to the first preferred embodiment;

FIGS. 8A and 8B are graphs showing the amounts of positional deviations before performing the offset according to the first preferred embodiment;

FIGS. 9A and 9B are graphs for calculating the orientation and magnitude of the offset according to the first preferred embodiment; and

FIGS. 10A and 10B are graphs showing the amounts of positional deviations after performing the offset according to the first preferred embodiment.

### DESCRIPTION OF THE PREFERRED EMBODIMENTS

A method of manufacturing a liquid crystal display device according to the present invention is characterized by the provision of an alignment mark not for each display area but for each array shot area. Further, this alignment mark consists of marks provided for the respective layers forming an array substrate and a color filter (CF) substrate. A preferred embodiment will be described below in detail.

### First Preferred Embodiment

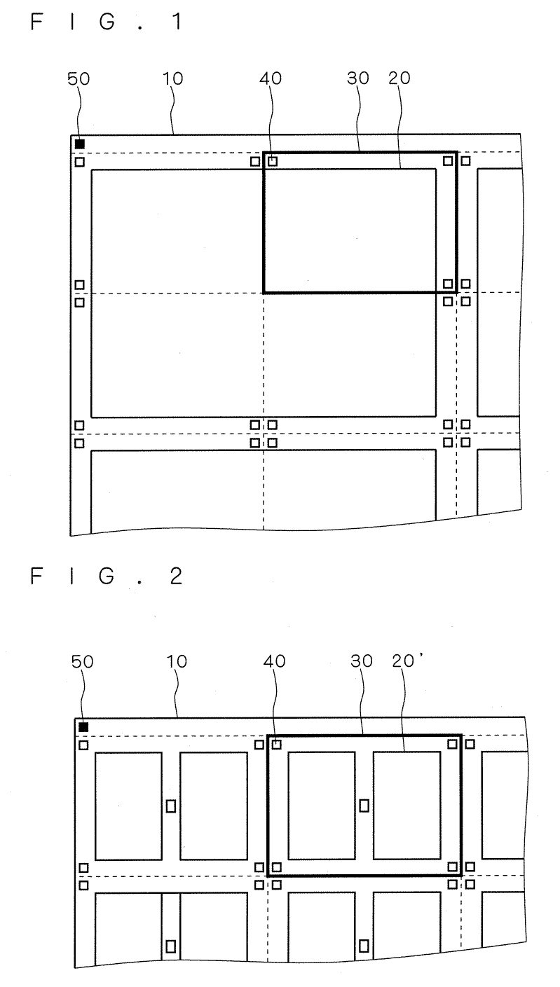

FIG. 1 is a top view illustrating an example of an array substrate used in a liquid crystal display device according to a first preferred embodiment of the present invention.

As shown, a plurality of display areas 20 each of which corresponds to one display substrate mounted on one liquid crystal display device are formed on an array substrate 10 by stepper exposure. Although not shown in FIG. 1, a pixel electrode, a thin film transistor, a source line, a gate line, and the like are formed in each of the display areas 20. The array substrate 10 is divided into array shot areas 30 (enclosed with a thick line) serving as shot units at the time of divided exposure. In FIG. 1, one display area 20 is divided into four array shot areas 30. Namely, one array shot area 30 includes a quarter of the display area 20.

One array shot area 30 is provided with at least one (three in FIG. 1) alignment mark 40. The array substrate 10 has a rectangular shape, and is provided with a superimposition mark 50 at the corner thereof which is used as the reference for superimposing the array substrate 10 and the CF substrate.

FIG. 2 is a top view illustrating another example of the array substrate. While one array shot area 30 includes a quarter of the display area 20 in FIG. 1, one array shot area 30 includes two display areas 20′ in FIG. 2. In FIG. 2, one array shot area 30 is provided with five alignment marks 40.

Typically, the size of the array shot area 30 depends on the type of an exposure device, and the size of the display area 20 depends on the type of a liquid crystal display device. Thus, the display area 20 is bigger than the array shot area 30, as shown in FIG. 1, in a large liquid crystal display device. Conversely, the display area 20′ is smaller than the array shot area 30, as shown in FIG. 2, in a small liquid crystal display device.

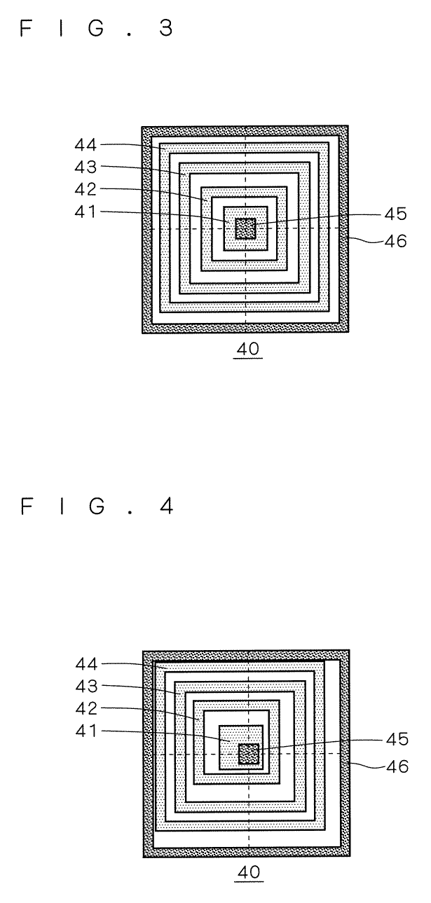

FIG. 3 is a top view illustrating the configuration of the alignment mark 40 shown in FIGS. 1 and 2. The alignment mark 40 consists of marks 41 to 44 (first alignment mark) provided for each layer on the array substrate 10 side, and marks 45 to 46 (second alignment mark) provided for each layer on the CF substrate side. These marks 41 to 46 have rectangular shapes of different sizes. With no positional deviations at all among the respective layers of the array substrate 10 and the CF substrate, the alignment mark 40 is designed in such a manner that the centers of all the marks 41 to 46 match, as shown in FIG. 3. FIG. 4 is a top view illustrating the configuration of the alignment mark 40 when the centers of the marks 41 to 46 deviate from one another due to positional deviations among the respective layers of the array substrate 10 and the CF substrate.

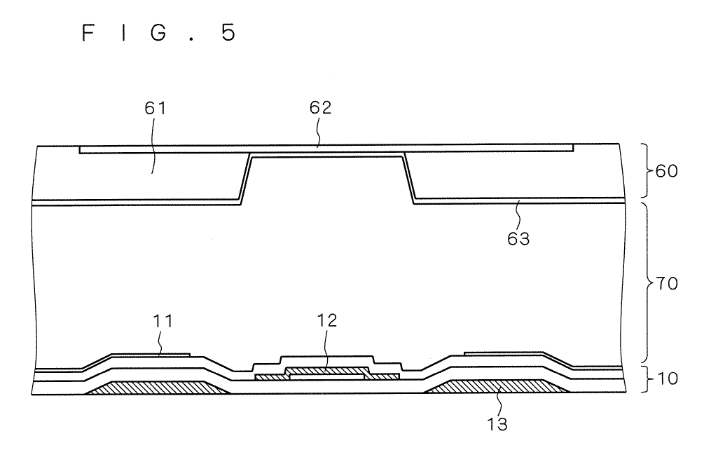

FIG. 5 is a cross-sectional view illustrating the structure of the liquid crystal display device. As shown, the liquid crystal display device includes the array substrate 10 (first substrate) and a CF substrate 60 (second substrate) joined to each other, and a liquid crystal layer 70 interposed between those substrates. A liquid crystal display element included in the liquid crystal layer 70 is controlled by the pixel electrodes and the like on the array substrate 10. Light having passed through the liquid crystal display element passes through the CF substrate 60 to thereby emit a predetermined color. The array substrate 10 is subjected to divided exposure in units of the array shot area 30, whereas the CF substrate 60 is subjected to whole-surface collective exposure.

As shown in FIG. 5, the array substrate 10 includes a plurality of layers such as an ITO (Indium Tin Oxide) layer 11, a source line layer 12, and a gate line layer 13. The CF substrate 60 includes a plurality of layers such as a color material layer 61, a BM (Black Matrix: light-shielding black color material) layer 62, and an ITO layer 63. Utilizing these layers, the marks 41 to 44 can be provided for the plurality of layers of the array substrate 10, and the marks 45 to 46 for the plurality of layers of the CF substrate 60. The array substrate 10 and the CF substrate 60 each have one superimposition mark 50 provided for one of its layers.

Correction of positional deviation in the method of manufacturing the liquid crystal display device according to the first preferred embodiment will now be described.

First, the array substrate 10 and the CF substrate 60 are made. In making those substrates, the respective layers of the array substrate 10 are provided with the marks 41 to 44, and the respective layers of the CF substrate 60 with the marks 45 to 46, respectively, as mentioned above. Further, at least one alignment mark 40, which consists of the marks 41 to 46, is provided for the array shot area 30 and an array shot corresponding area defined on the CF substrate 60 correspondingly to the array shot area 30.

Next, the positions of the marks 41 to 44 and the marks 45 to 46 are measured with respect to the thus made array substrate 10 and CF substrate 60, respectively. In measuring the positions, the array substrate 10 and the CF substrate 60 are kept in a chamber and adjusted to the same temperature. After the temperature has been stabilized, a precision coordinate measurement device is used to measure the central position coordinates of the marks 41 to 44 and the marks 45 to 46 with respect to the array substrate 10 and the CF substrate 60, respectively and separately. The position coordinates of the superimposition marks 50 are also measured with respect to the array substrate 10 and the CF substrate 60, respectively. For brevity, the following is based on the assumption that positional deviations among the respective layers of the CF substrate 60 are relatively small, and the central position coordinates of the marks 45 to 46 almost match. However, the matching of the central position coordinates of the marks 45 to 46 is not necessarily required.

Next, the position coordinates of the superimposition marks 50 thus measured are used to superimpose the array substrate 10 and the CF substrate 60 on calculation (namely, move all coordinate data in parallel so that the position coordinates of the superimposition mark 50 on the array substrate 10 match the position coordinates of the superimposition mark 50 on the CF substrate 60). Then, the amounts of positional deviations from the central position coordinates of the mark 45 (or mark 46) are calculated with respect to the respective central position coordinates of the marks 41 to 44.

The amounts of positional deviations thus calculated are then averaged in units of the array shot area 30. In FIG. 1, for example, one array shot area 30 is provided with three alignment marks 40 each of which includes the four marks 41 to 44 on the array substrate 10. Thus, in one array shot area 30, the average amount of positional deviations with reference to the array shot corresponding area is calculated by averaging 4×3=12 amounts of positional deviations.

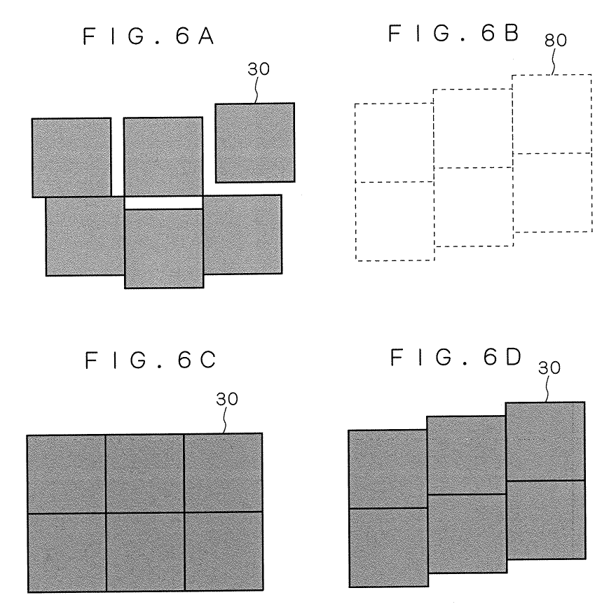

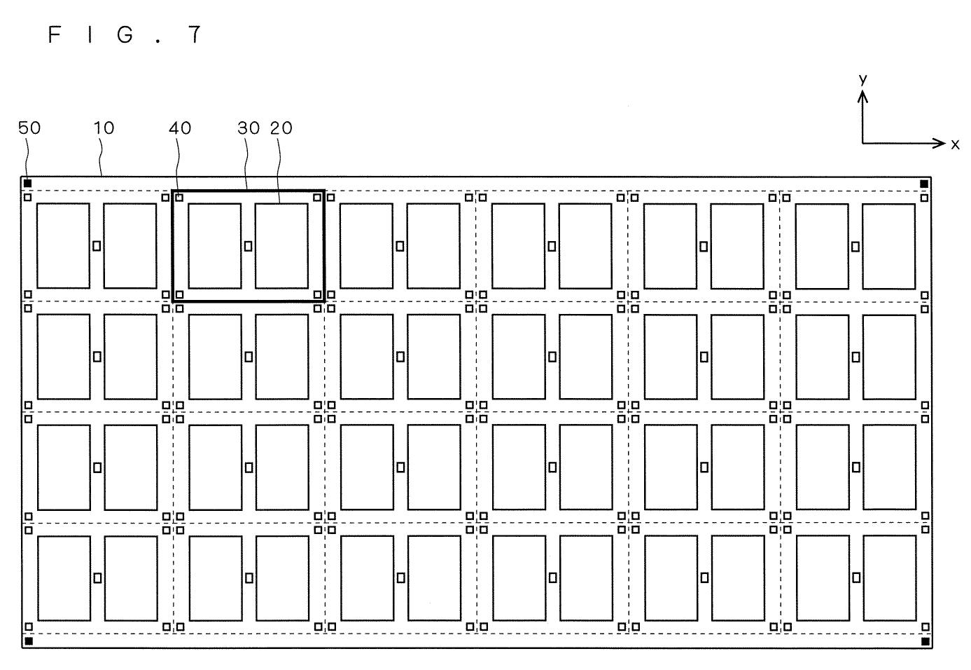

Subsequently, as illustrated in FIGS. 6A to 6D, the positions of the array shot areas 30 are corrected by using the average amount of positional deviations thus calculated.

FIG. 6A illustrates a plurality of array shot areas 30 (first shot area) whose positions deviate from one another, and FIG. 6B illustrates a plurality of array shot corresponding areas 80 (first shot corresponding area) whose positions deviate from one another. The CF substrate 60, which is subjected to whole-surface collective exposure as mentioned above, is not divided into shot units. For the sake of explanation, however, the array shot corresponding areas 80 are defined on the CF substrate 60 correspondingly to the array shot areas 30, as units where the marks 45 to 46 are provided. Namely, in FIG. 6B, materials disposed in the array shot corresponding areas 80 defined on the CF substrate 60 correspondingly to the array shot areas 30 deviate from one another due to the deviation of the CF substrate 60 and the like.

In FIG. 6C, the positional deviations among the plurality of array shot areas 30 are corrected without consideration of the positional deviations among the array shot corresponding areas 80. With such corrections, the positional deviations among the array shot areas 30 are reduced, but the positional deviations of the array shot areas 30 from the array shot corresponding areas 80 increase.

In the first preferred embodiment, the positions of the plurality of array shot areas 30 are corrected in accordance with the positions of the plurality of array shot corresponding areas 80, as illustrated in FIG. 6D. With such corrections, the positional deviations among the array shot areas 30 increase, but the positional deviations of the array shot areas 30 from the array shot corresponding areas 80 can be reduced.

As described above, in the method of manufacturing the liquid crystal display device according to the first preferred embodiment, positional deviations are corrected in units of the array shot area 30 by using at least one alignment mark 40 provided for the array shot area 30. The positional deviations can therefore be corrected appropriately even when the display area 20 is larger than the array shot area 30, as illustrated in FIG. 1, thus improving the alignment accuracy between the array substrate 10 and the CF substrate 60. This allows display failures to be reduced such as the unevenness on the border between shots.

Further in the method of manufacturing the liquid crystal display device according to the first preferred embodiment, positional deviations are corrected by using the array substrate 10 and the CF substrate 60 having the marks provided for their respective layers. Accordingly, the positional deviations among the respective layers in the substrates can be corrected more accurately than when each substrate is provided with only one mark, thus further improving the alignment accuracy.

The positional deviations are corrected in units of the array shot area 30 above. Alternatively, the positional deviations may be corrected in units of the whole substrate by performing a predetermined offset in superimposing the substrates. In such case, the orientation of the offset and the magnitude (amount) of the offset may be determined in such a manner that an average value on the whole of the array substrate 10 of the amounts of positional deviations calculated from the measured position coordinates becomes a minimum. Still alternatively, the positional deviations can be corrected in units of the array shot area 30, as well as by performing the offset.

Although shown to have a rectangular shape above, it will be appreciated that the marks 41 to 46 could have other shapes that are the same and of different sizes from one another.

Further, although the CF substrate 60 is subjected to whole-surface collective exposure above, divided exposure may alternatively take place in units of area larger than the array shot area 30, for example.

Moreover, the divided exposure of the array substrate 10 as a first substrate, and the whole-surface collective exposure of the CF substrate 60 as a second substrate, as mentioned above, may alternatively be replaced by divided exposure of the CF substrate 60 as a first substrate, and whole-surface collective exposure of the array substrate 10 as a second substrate. In such case, the array shot areas 30 are replaced by color filter shot areas, and the array shot corresponding areas 80 are replaced by color filter shot corresponding areas in FIG. 6.

An offset based on actually measured values with an array substrate having such structure as is shown in FIG. 7 will now be described. In FIG. 7, a total of twenty-four array shot areas 30 shown in FIG. 2 are provided, with six of them being provided horizontally (x direction) and four of them vertically (y direction). Namely, the alignment marks 40 are provided at 5×24=120 points. This sample is designed such that an acceptable amount of positional deviation is not more than 1.5 μm.

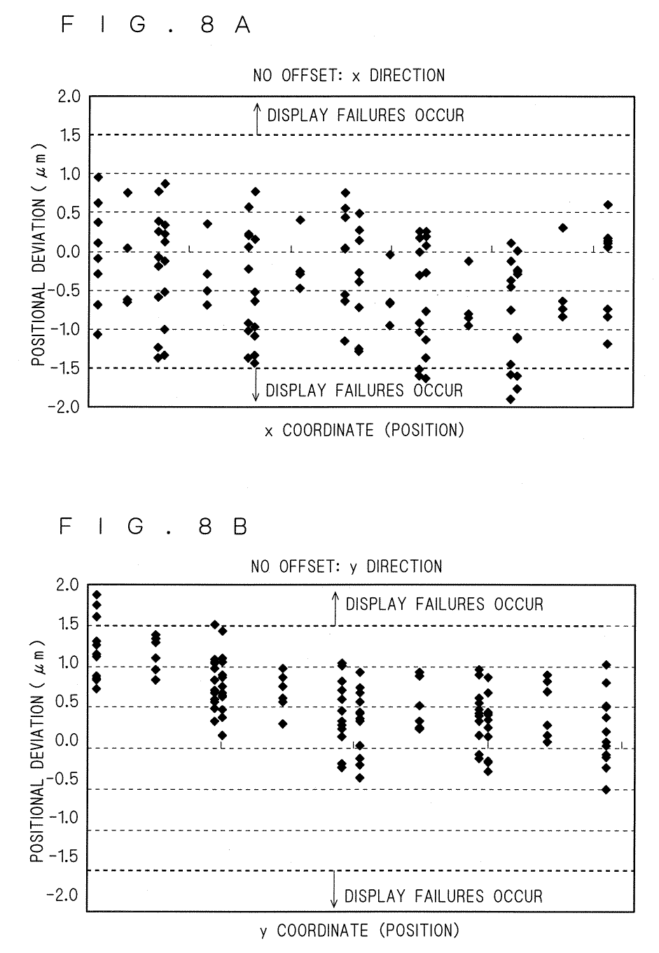

FIGS. 8A and 8B are graphs showing actually measured amounts of positional deviations before performing the offset. In FIG. 8A that shows the actually measured amounts of positional deviations in the x direction in FIG. 7, an average value is −0.40 μm, and a maximum value (absolute value) is 1.90 μm. Thus, seven points (5.4%) on the array substrate are failures. In FIG. 8B that shows the actually measured amounts of positional deviations in the y direction in FIG. 7, an average value is 0.59 μm, and a maximum value (absolute value) is 1.87 μm. Thus, four points (2.6%) on the array substrate are failures.

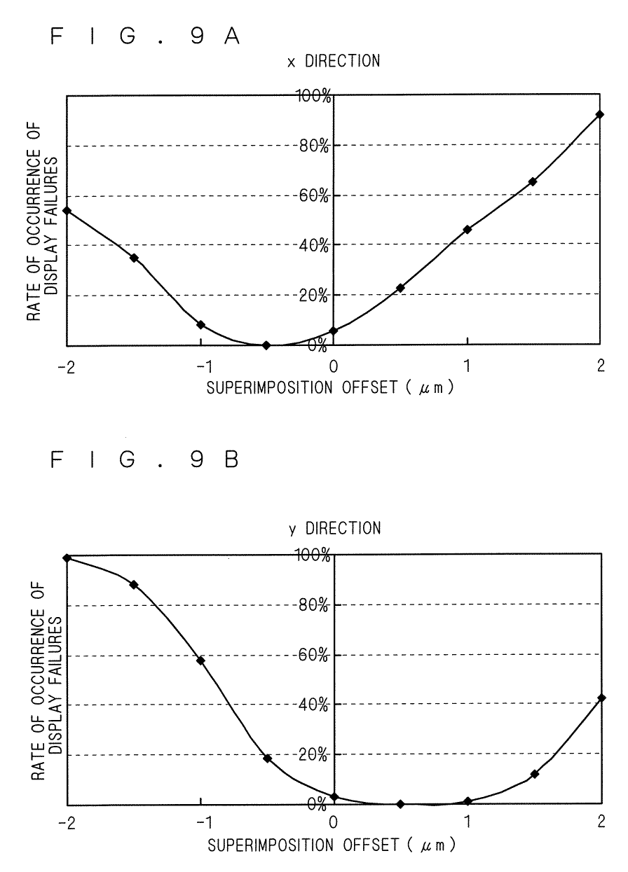

FIGS. 9A and 9B are graphs for calculating the orientation and magnitude of an offset so that an average value on the whole of the array substrate 10 of the amounts of positional deviations calculated from the position coordinates measured at the alignment marks 40 of 120 points becomes a minimum. As shown in FIG. 9A, the rate of occurrence of failures becomes 0% in the x direction when performing an offset of −0.47 μm. And as shown in FIG. 9B, the rate of occurrence of failures becomes 0% in the y direction when performing an offset of +0.68 μm.

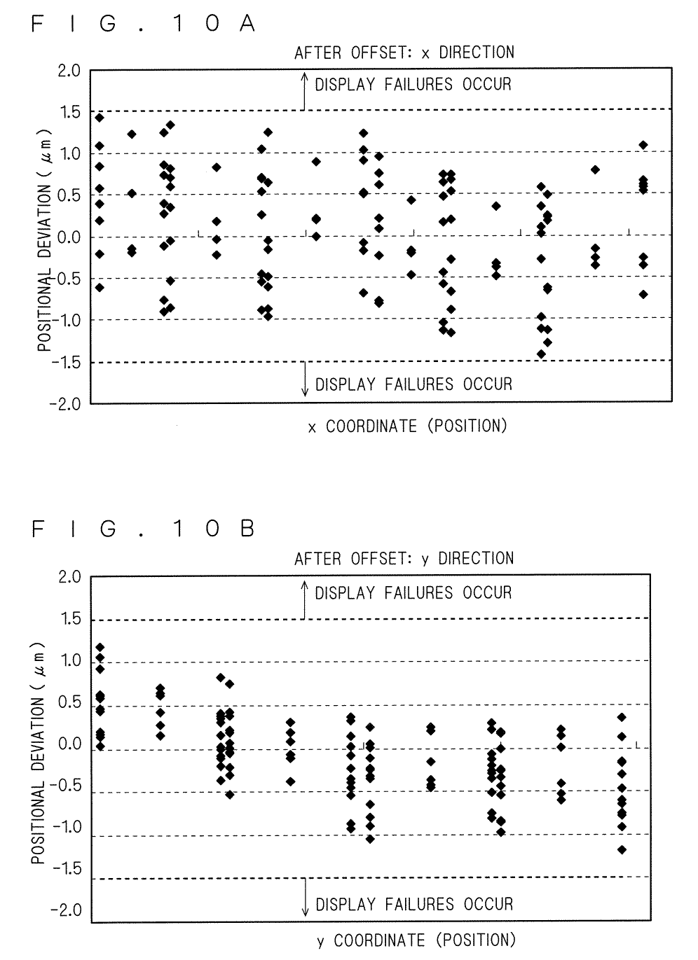

FIGS. 10A and 10B show results after performing the offsets in FIGS. 8A and 8B based on the calculations shown in FIGS. 9A and 9B. Namely, FIG. 10A shows the result of an offset of −0.47 μm in FIG. 8A, and FIG. 10B of an offset of +0.68 μm in FIG. 8B. In both FIGS. 10A and 10B, the amount of positional deviation is not more than 1.5 μm in all points. With such offsets, the rate of occurrence of failures due to positional deviations can be reduced to 0% on calculation. The offsets calculated in this manner were actually used to correct positional deviations in units of the array substrate 10. The result was a high yield without the occurrence of display failures.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a liquid crystal display device having a first substrate and a second substrate being oppositely arranged, said method comprising the steps of:
(a) making said first substrate while forming at least one first alignment mark in each of a plurality of first shot areas, said first shot areas being divided by divided exposure and smaller than a display area on said first substrate;
(b) making said second substrate while forming a second alignment mark corresponding to said first alignment mark in each of first shot corresponding areas, said first shot corresponding areas corresponding on said second substrate to said first shot areas;
(c) determining a positional deviation of said first alignment mark from said second alignment mark; and
(d) correcting a position of each of said first shot areas in accordance with a position of each of said first shot corresponding areas based on said positional deviation determined by said step (c).

2. A method of manufacturing a liquid crystal display device having a first substrate and a second substrate being oppositely arranged, said method comprising the steps of:
(a) making said first substrate while forming at least one first alignment mark in each of a plurality of first shot areas, said first shot areas being divided by divided exposure and smaller than a display area on said first substrate;
(b) making said second substrate while forming a second alignment mark corresponding to said first alignment mark in each of first shot corresponding areas, said first shot corresponding areas corresponding on said second substrate to said first shot areas;
(c) determining a positional deviation of said first alignment mark from said second alignment mark;
(d-1) determining an amount of offset for said first substrate based on said positional deviation determined by said step (c); and
(e) displacing said first substrate in accordance with said amount of offset determined by said step (d-1).

3. A method of manufacturing a liquid crystal display device having a first substrate and a second substrate being oppositely arranged, said method comprising the steps of:
(a) making said first substrate while forming at least one first alignment mark in each of a plurality of first shot areas, said first shot areas being divided by divided exposure and smaller than a display area on said first substrate;
(b) making said second substrate while forming a second alignment mark corresponding to said first alignment mark in each of first shot corresponding areas, said first shot corresponding areas corresponding on said second substrate to said first shot areas;
(c) determining a positional deviation of said first alignment mark from said second alignment mark;
(d) correcting a position of each of said first shot areas in accordance with a position of each of said first shot corresponding areas based on said positional deviation determined by said step (c);
(d-1) determining an amount of offset for said first substrate based on said positional deviation determined by said step (c); and
(e) displacing said first substrate in accordance with said amount of offset determined by said step (d-1).

4. The method of manufacturing a liquid crystal display device according to claim 1, wherein
said first substrate is an array substrate,
said second substrate is a color filter substrate,
said first shot area is an array shot area, and
said first shot corresponding area is an array shot corresponding area.

5. The method of manufacturing a liquid crystal display device according to claim 2, wherein
said first substrate is an array substrate,
said second substrate is a color filter substrate,
said first shot area is an array shot area, and
said first shot corresponding area is an array shot corresponding area.

6. The method of manufacturing a liquid crystal display device according to claim 3, wherein
said first substrate is an array substrate,
said second substrate is a color filter substrate,
said first shot area is an array shot area, and
said first shot corresponding area is an array shot corresponding area.

7. The method of manufacturing a liquid crystal display device according to claim 1, wherein
said first substrate is a color filter substrate,
said second substrate is an array substrate,
said first shot area is a color filter shot area, and
said first shot corresponding area is a color filter shot corresponding area.

8. The method of manufacturing a liquid crystal display device according to claim 2, wherein
said first substrate is a color filter substrate,
said second substrate is an array substrate,
said first shot area is a color filter shot area, and
said first shot corresponding area is a color filter shot corresponding area.

9. The method of manufacturing a liquid crystal display device according to claim 3, wherein
said first substrate is a color filter substrate,
said second substrate is an array substrate,
said first shot area is a color filter shot area, and
said first shot corresponding area is a color filter shot corresponding area.

10. The method of manufacturing a liquid crystal display device according to claim 1, wherein
in said step (a), said first alignment mark is formed in each of a plurality of layers forming said first shot area.

11. The method of manufacturing a liquid crystal display device according to claim 2, wherein
in said step (a), said first alignment mark is formed in each of a plurality of layers forming said first shot area.

12. The method of manufacturing a liquid crystal display device according to claim 3, wherein
in said step (a), said first alignment mark is formed in each of a plurality of layers forming said first shot area.

13. The method of manufacturing a liquid crystal display device according to claim 1, wherein
in said step (b), said second alignment mark is formed in each of a plurality of layers forming said first shot corresponding area.

14. The method of manufacturing a liquid crystal display device according to claim 2, wherein
in said step (b), said second alignment mark is formed in each of a plurality of layers forming said first shot corresponding area.

15. The method of manufacturing a liquid crystal display device according to claim 3, wherein
in said step (b), said second alignment mark is formed in each of a plurality of layers forming said first shot corresponding area.
